(19) United States
(12) Patent Application Publication
(10) Pub. No.: US 2015/0155042 A1
(43) Pub. Date: Jun. 4, 2015

(54) SEMICONDUCTOR MEMORY DEVICE

(71) Applicant: KABUSHIKI KAISHA TOSHIBA, Tokyo (JP)

(72) Inventor: Toyokazu EGUCHI, Tokyo (JP)

(73) Assignee: KABUSHIKI KAISHA TOSHIBA, Tokyo (JP)

(21) Appl. No.: 14/268,251

(22) Filed: May 2, 2014

(30) Foreign Application Priority Data
Dec. 2, 2013 (JP) 2013-249485

(51) Int. Cl. G11C 16/10; H01L 27/115

(52) U.S. Cl. CPC G11C 16/10; H01L 27/11517

(57) ABSTRACT

A NAND DC-DC converter includes two output terminals. Each output terminal is connected to several multi-chip packages in each of which a plurality of NAND flash memory chips are provided. Phases of voltages which are output from the output terminals are different by 180 degrees. In addition, a maximum of the output voltages are approximately one-half of a maximum of an input voltage supplied to the NAND DC-DC converter

### CROSS-REFERENCE TO RELATED APPLICATION

This application is based upon and claims the benefit of priority from Japanese Patent Application No. 2013-249485, filed Dec. 2, 2013, the entire contents of which are incorporated herein by reference.

### FIELD

Embodiments described herein relate generally to a semiconductor memory device having a non-volatile semiconductor memory element, for example, a solid state drive (SSD).

### BACKGROUND

A large capacity SSD which includes a plurality of non-volatile semiconductor memory elements (for example, multi-chip module including a plurality of NAND flash memory chips) has become common.

In the related art, a step-down DC-DC converter of a single output type (one channel) is used to supply a voltage for reading and writing to the plurality of semiconductor memory elements. With such a configuration, a voltage is uniformly supplied to all of the semiconductor memory elements.

In such a configuration, a peak current of input power is determined by a pulse current which is supplied to an inductor when a PWM control is turned on (ON Duty). On the other hand, when the PWM control is turned off (OFF Duty), there is almost no current of the input power. For this reason, a current fluctuation (ripple current), and a voltage fluctuation (ripple voltage) during such a time are influenced by a decoupling capacitor which is connected to a power input terminal. In order to reduce the magnitudes of the ripple current and the ripple voltage, it is necessary to use a large capacity decoupling capacitor.

### DESCRIPTION OF THE DRAWINGS

FIG. 1 illustrates a block diagram of a semiconductor memory device according to a present embodiment.

FIG. 2 illustrates a block diagram of a DC-DC converter in the semiconductor memory device according to the present embodiment.

FIG. 3 illustrates a voltage waveform in an output terminal of a DC-DC converter in a comparative example.

FIG. 4 illustrates a voltage waveform in a first output terminal of the DC-DC converter in the semiconductor memory device according to the present embodiment.

FIG. 5 illustrates a voltage waveform in a second output terminal of the DC-DC converter in the semiconductor memory device according to the present embodiment.

FIG. 6 illustrates a voltage waveform in a first switching terminal of the DC-DC converter in the semiconductor memory device according to the present embodiment.

FIG. 7 illustrates a voltage waveform in a second switching terminal of the DC-DC converter in the semiconductor memory device according to the present embodiment.

FIG. 8 illustrates a voltage waveform in an intermediate point between the first switching terminal of the DC-DC converter and a NAND flash memory which is connected thereto in the semiconductor memory device according to the present embodiment.

FIG. 9 illustrates a voltage waveform in an intermediate point between the second switching terminal of the DC-DC converter and a NAND flash memory which is connected thereto in the semiconductor memory device according to the present embodiment.

### DETAILED DESCRIPTION

In one or more embodiments, power is efficiently supplied to a plurality of semiconductor memory elements.

In general, according to one embodiment, a semiconductor memory device includes a first semiconductor memory element group including a plurality of semiconductor memory elements; a second semiconductor memory element group including a plurality of semiconductor memory elements; and a circuit (for example, DC-DC converter) including an input terminal and first and second output terminals. In the semiconductor memory device, a first voltage output through the first output terminal is supplied to the first semiconductor memory element group, and a second voltage output through the second output terminal is supplied to the second semiconductor memory element group, and the first and second voltages have different phases. The semiconductor memory device may include a controller that controls writing and reading of the semiconductor memory element. In addition, the controller may have a channel configuration in which each of its output terminals correspond to a channel, and is directly or indirectly connected to a different one of the semiconductor memory elements. For example, the controller may have a configuration in which eight output terminals are provided (8 channels), and each output terminal is connected to a different one of eight semiconductor memory elements. In this case, the first voltage is supplied to four semiconductor memory elements, and the second voltage is supplied to the other four semiconductor memory elements. In addition, the semiconductor memory element may be a multi-chip module (MCP) which includes a plurality of semiconductor chips (NAND flash memory). In addition, the first and second voltages are used when reading and writing information in a non-volatile semiconductor element, and are for example, 2.5 V to 3.0 V. At the same time, it is possible to separately supply a power supply of 1.8 V for the interface. Accordingly, in a case of a semiconductor memory element using eight MCPs, a voltage of approximately 2.5 V to 3.0 V is supplied to four MCPs on one side from the first output terminal which is provided in the DC-DC converter, a voltage of approximately 2.5 V to 3.0 V is supplied to four MCPs on the other side from the second output terminal, and a voltage of 1.8 V for input-output is supplied to all of the eight MCPs from the separate output terminal which is provided in the DC-DC converter. In addition, it is possible to have a configuration in which each of the control terminals (eight channels in total) of the controller controls one MCP, respectively.

In addition, the first and second voltages may be generated using a pulse width modulation (PWM) technology. In this case, it is possible easily to generate phases of the first and second voltages that are different from each other by 180 degrees by causing phases of a reference to be different by 180 degrees. It is preferable that the number of the semiconductor memory elements which are respectively connected to the first and second output terminals to be the same, and for the output terminals to encounter the same load. In such a configuration, a voltage output from the first output terminal and a current flowing therefrom, and a voltage output from the second output terminal and a current flowing therefrom are approximately the same except for the phase.

In addition, efficiency is gained when a peak voltage between the first and second voltages is set to be approximately one-half of a peak voltage which is input to the DC-DC converter.

In addition, third and fourth output terminals, or the like, may be provided. When there are three output terminals, it is preferable that phases of output voltages of the DC-DC converter (switching voltage) be shifted by 120 degrees, respectively. It is preferable that the number of semiconductor memory elements (MCP) which are connected to each output terminal be set to the same number, or for the output terminals to encounter the same load. When there are four output terminals, it is preferable that phases of the output voltages (switching voltage) of the DC-DC converter be shifted by 90 degrees, respectively. Similarly, it is possible to make various modifications to exemplary embodiments to the extent that they may be easily conceived by a person skilled in the art.

The connection in the exemplary embodiments of the present application also includes a case of being indirectly connected in a reasonable range, not only a case of being physically connected, directly.

It is possible to efficiently supply power in a semiconductor memory device in which a plurality of non-volatile semiconductor memory elements are used, based on disclosed embodiments.

### First Embodiment

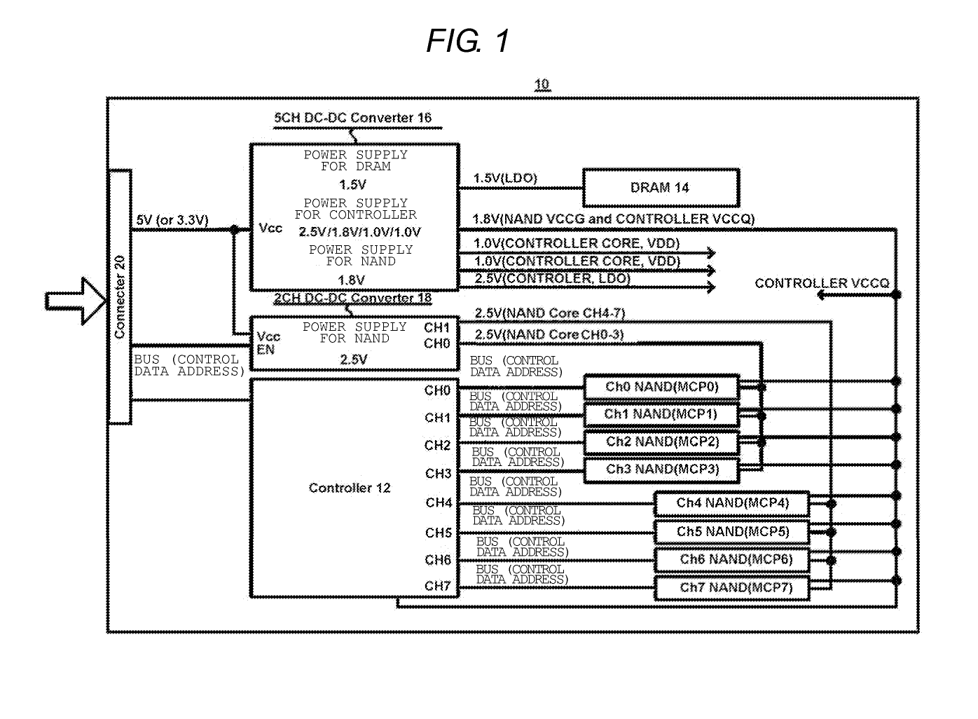

FIG. 1 illustrates a block diagram of a semiconductor memory device 10 according to the present embodiment. The semiconductor memory device includes eight multi-chip packages (MCP) (MCP0 to MCP7) which include a plurality of non-volatile semiconductor memories (NAND flash memory chips). The semiconductor memory device 10 further includes a controller 12 which controls reading and writing of information from and to each NAND flash memory chip provided in the MCP0 to MCP7, and a DRAM 14 which temporarily stores information, and functions as a cache for transferring data between a host device and each MCP, and a working area memory. In addition, the semiconductor memory device further includes a five-channel DC-DC converter 16 which includes output terminals for supplying a DC voltage to the controller and the DRAM, a two-channel DC-DC converter 18 which similarly includes output terminals, and a connector 20 which receives a control signal for controlling voltages supplied to the DC-DC converters 16 and 18, the DRAM 14, the MCPs 0 to 7, and the controller 12. The connector 20 may be connected to a host device (not shown) (for example, personal computer, or server). In addition, a part of the NAND flash memory chips may be used as a cache without using the DRAM. In addition, a substrate on which the controller 12 is mounted, and a substrate on which the MCP0 to MCP7 are mounted may be separately provided, without arranging all of components on the same substrate. In addition, it is also possible to have a configuration in which the controller is arranged in the host device, and the controller is not provided in the semiconductor memory device.

Since the controller 12 controls eight MCPs 0 to 7, the controller includes input-output units of eight channels from a channel 0 (CH0) to a channel 7 (CH7). Each channel includes a plurality of input-output terminals, and performs a delivery of a control signal for executing a control of reading and writing, a selection of a block, wear-leveling, or the like, with respect to each MCP and the NAND flash memory chip which is included therein, or data, respectively, between each channel and the MCPs 0 to 7. Accordingly, the controller 12 may control the eight semiconductor memory elements of MCPs 0 to 7 in parallel. In addition, the controller 12 is connected to the DRAM 14 (not shown), and also controls operations of the DRAM 14. The DC-DC converter 16 supplies a Voltage Drain (VDD) of 1.0 V, a voltage VCCQ of 1.8 V, and a voltage LDO of 2.5 V, which are defined according to a JEDEC standard, with respect to the controller 12.

The DRAM 14 functions as a cache for transferring data to the MCPs 0 to 7, and stores user data, managing data, or the like. The DC-DC converter 16 supplies a voltage LDO of 1.5 V to the DRAM.

Each of the MCPs 0 to 7 includes, for example, sixteen NAND flash memory chips (not shown), and the MCPs 0 to 7 are multi-chip modules which are formed with 128 GB in total, and have a storage capacity of 1 TB in total in the entire semiconductor memory device 10. The DC-DC converter 16 supplies a VCCQ of 1.8 V to the MCPs 0 to 7 as a power supply for an input-output circuit. In addition, the DC-DC converter 18 supplies a voltage of 2.5 V for being used in reading, writing, or the like, of the information with respect to a core of the NAND flash memory chip, to each of the MCPs 0 to 7.

The connector 20 has a configuration in which the connector may be connected to an external device which is a host device. The connector includes a plurality of terminals, supplies a power supply of 5 V (or 3.3 V) which is supplied to the DC-DC converters 16 and 18, and includes an enable terminal EN which controls operations of the DC-DC converter 18 as necessary.

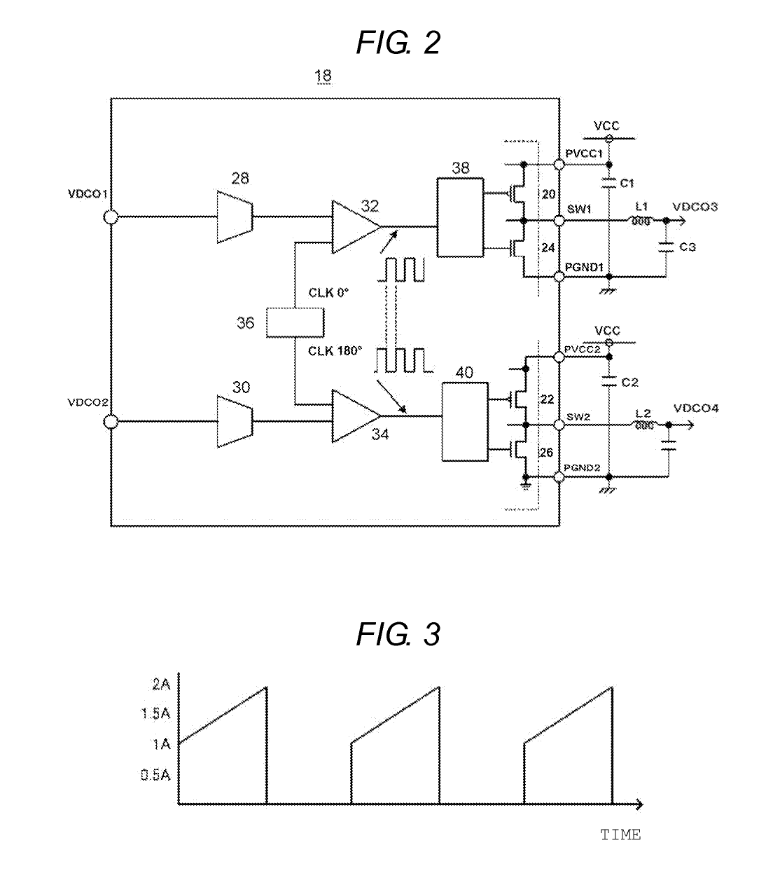

FIG. 2 illustrates an internal configuration of the DC-DC converter 18. As illustrated in FIG. 2, the DC-DC converter 18 includes DC power supply voltage input terminals VDCO1 and VDCO2. In addition, the DC-DC converter includes a P channel MOSFET 20 and an N channel MOSFET 24 which is connected thereto in series, and a P channel MOSFET 22 and an N channel MOSFET 26 which is connected thereto in series. In addition, the DC-DC converter includes a source terminal PVCC1 (or PVCC2) of the P channel MOSFET 20 (or P channel MOSFET 22), SW1 (or SW2) which is a drain terminal of the P channel MOSFET 20 (or P channel MOSFET 22), and a drain terminal of the N channel MOSFET 24 (or N channel MOSFET 26), and a terminal PGND1 (or PGND2) which is a source terminal of the N channel MOSFET 24 (or N channel MOSFET 26), and is connected to a ground. In addition, the DC-DC converter 18 includes an EN terminal (not shown) which stops the entire operation of the DC-DC converter 18. Accordingly, when it is not necessary to operate the MCPs 0 to 7, the host device has a configuration in which only operations of the DC-DC converter are stopped using the EN terminal, and power consumption may be suppressed.

The input terminal VDCO1 (or input terminal VDCO2) is connected to an input terminal of a differential amplifier 28 (or differential amplifier 30) which functions as an error amplifier. The differential amplifier configures a feedback control which is not shown, and an output terminal thereof is connected to an input terminal of a PWM comparator 32 (or PWM comparator 34).

In addition, the DC-DC converter 18 includes an oscillator 36, which outputs a square wave CLK0, and a square wave CLK180 whose phase is different from that of the square wave CLK0 by 180 degrees, respectively. The wave CLK0 is supplied to the other input terminal of the PWM. comparator 32, and the wave CLK180 is supplied to the other input terminal of the PWM comparator 34.

The DC-DC converter 18 further includes gate drivers 38 and 40. An output on the high side of the gate driver 38 (or gate driver 40) is connected to a gate of the P channel MOSFET 20 (or P channel MOSFET 22), and an output on the low side is connected to a gate of the N channel MOSFET 24 (or N channel MOSFET 26).

The terminal SW1 (or SW2) of the DC-DC converter 18 is connected to a coil L1 (or L2) which functions as an inductor. As a terminal VDCO3 (or terminal VDCO4), the other end of the coil L1 (or L2) is connected to an input terminal of a voltage for reading and writing of the NAND chip which is provided in the MCPs 0 to 3 (or MCPs 4 to 7) as illustrated in FIG. 1. The terminal VDCO3 (or terminal VDCO4) is connected to a capacitor C3 (or capacitor C4), and the other end of the capacitor C3 (or capacitor C4) is connected to the ground and the terminal PGND1 (or PGND2). In addition, the terminal PVCC1 (or PVCC2) is connected to a capacitor C1 (or capacitor C2), and the other end of the capacitor C1 (or capacitor C2) is connected to the ground and the terminal PGND1 (or PGND2). Accordingly, the channel CH0 of the DC-DC converter 18 supplies a DC voltage for a core of the NAND chip in the MCPs 0 to 3 from the terminal VDCO3, and the channel CH1 supplies a DC voltage for a core of the NAND chip in the MCPs 4 to 7 from the terminal VDCO4. Since each MCP has the same configuration, a load between channels of the DC-DC converter is substantially the same.

Operations of the semiconductor memory device 10 including the above described configuration will be described below.

For example, a power voltage of 5 V is supplied to the DC-DC converters 16 and 18, respectively, through the connector 20 from the outside. As illustrated in FIG. 1, the DC-DC converter 16 supplies a power voltage to the DRAM 14, the MCPs 0 to 7, the controller 12, and the like.

On the other hand, a voltage of 5 V is supplied to the DC-DC converter 18 from the terminals VDCO1 and VDCO2 which are illustrated in FIG. 2.

A voltage which is input to the differential amplifier (Error Amp) 28 from the terminal VDCO1 is input to the PWM comparator 32 after a voltage level thereof is adjusted using a feedback configuration (not shown) which is provided in the differential amplifier 28.

Similarly, a voltage which is input to the differential amplifier (Error Amp) 30 from the terminal VDCO2 is input to the PWM comparator 34 after a voltage level thereof is adjusted using a feedback configuration (not shown) which is provided in the differential amplifier 30.

The oscillator 36 generates a first clock pulse of, for example, 1 MHz (cycle of 1 μs), and a second clock pulse of 1 MHz whose phase is different from the first clock pulse by 180 degrees. The first clock pulse is input to the PWM comparator 32, and the second clock pulse is input to the PWM comparator 34.

The PWM comparator 32 compares the input from the differential amplifier 28 to the input from the oscillator 36, and outputs a pulse signal with a phase of 0 degrees and 1 MHz as illustrated in FIG. 2. Similarly, the PWM comparator 34 compares the input from the differential amplifier 30 to the input from the oscillator 36, and outputs a pulse signal with a phase of 180 degrees and 1 MHz as illustrated in FIG. 2.

The output from the PWM comparator 32 is input to the gate driver 38. The gate driver 38 alternately switches a P type MOS transistor 20 and an N type MOS transistor 24 with a phase of 0 degrees, and in a cycle of 1 MHz.

Similarly, the output from the PWM comparator 34 is input to the gate driver 40. The gate driver 40 alternately switches a P type MOS transistor 22 and an N type MOS transistor 26 with a phase of 180 degrees, and in a cycle of 1 MHz.

Since the phase is different by 180 degrees in a control signal with respect to the gate driver 38, and in a control signal with respect to the gate driver 40, the N type MOS transistor 26 is in an ON state (P type MOS transistor 22 is in an OFF state) when the P type MOS transistor 20 is in an ON state (N type MOS transistor 24 is in an OFF state), and the P type MOS transistor 22 is in an ON state (N type MOS transistor 26 is in an OFF state) when the N type MOS transistor 24 is in an ON state (P type MOS transistor 20 is in an OFF state).

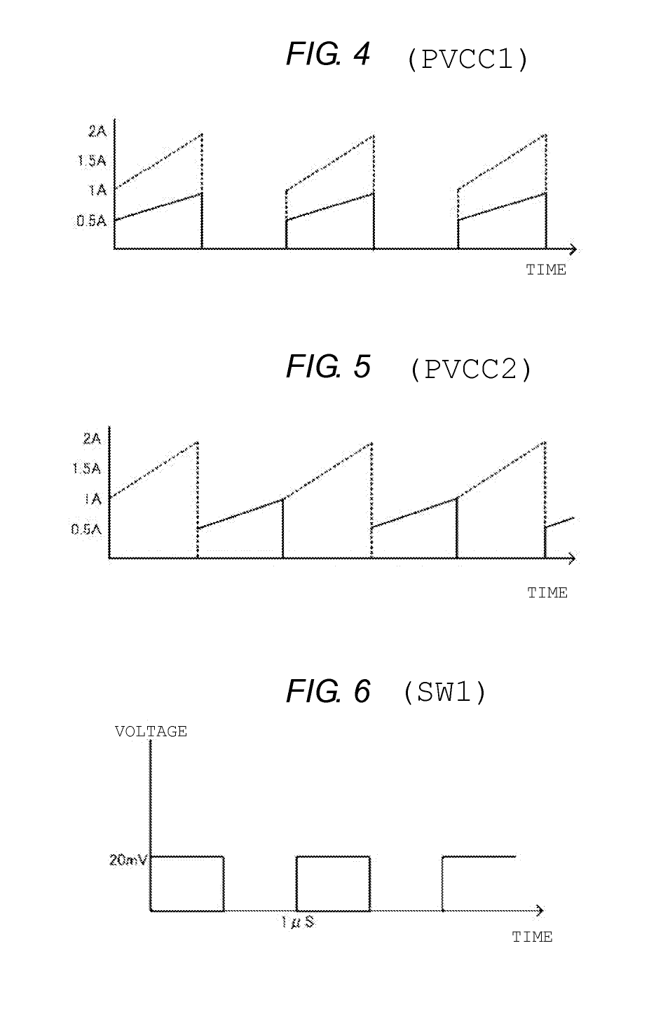

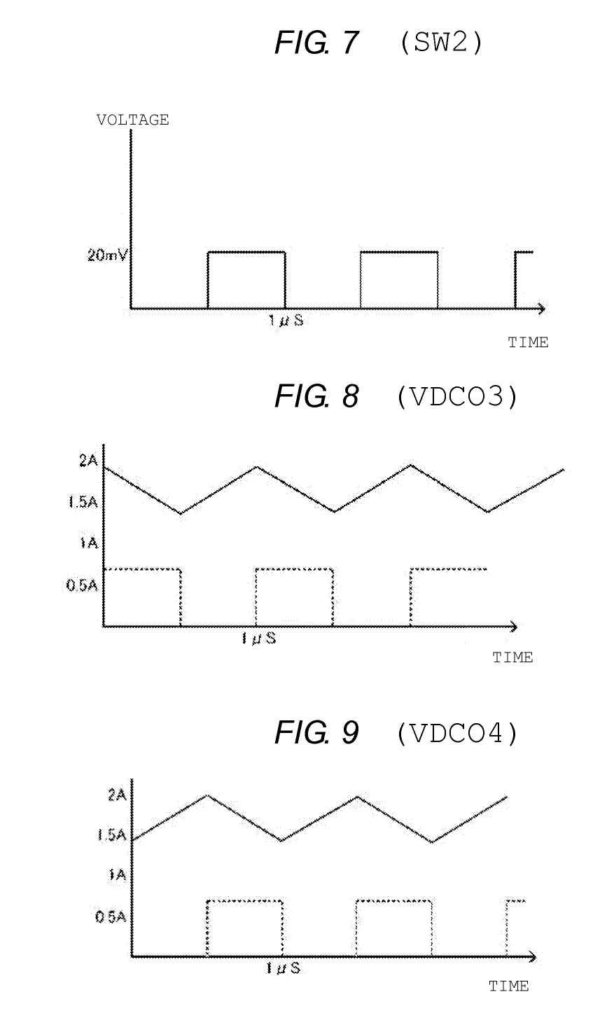

As a result, as illustrated in FIGS. 6 and 7, voltages in the terminals SW1 and SW2 are changed by differentiating phases by 180 degrees from each other in a cycle of 1 MHz. According to the present embodiment, an amplitude of a voltage is adjusted to approximately 20 mV. At this time, a current which flows in the terminal PVCC1 which is connected to a source of the P type MOSFET 20 is denoted by a solid line in FIG. 4, and a current which flows in the terminal PVCC2 which is connected to a source of the P type MOSFET 22 is denoted by a solid line in FIG. 5. In addition, as a comparison, a current in a case of the above-described single output type DC-DC converter of the related art is denoted by a solid line in FIG. 3, and is denoted by dotted lines in FIGS. 4 and 5. In addition, a current in the terminal VDCO3 which is at a position of being electrically connected to the terminal SW1 through the inductor L1, and of being electrically connected through the ground and the capacitor 3 varies with an amplitude of approximately 0.5 A about the center which is at 1.5 A, as illustrated in FIG. 8. Similarly, a current in the terminal VDCO4 varies, as illustrated in FIG. 9, and a phase thereof is different from the current change in the terminal VDCO3 by 180 degrees. In addition, as a reference, a voltage in the terminal SW1 (SW2) is denoted by a dotted line in FIG. 8 (FIG. 9).

In a comparative example, as illustrated in FIG. 3, the current gradually increases from a current of approximately 1.0 A to 1.5 A for approximately 0.5 μs, and then barely flows during a period of 0.5 μs to 1.0 μs.

On the other hand, according to the present embodiment, as illustrated in FIG. 4, a current which flows in the terminal PVCC1 gradually increases from a current of approximately 0.5 A to 1.0 A for approximately 0.5 μs, and then barely flows during a period of 0.5 μs to 1.0 μs. In addition, on the PVCC2 side, the current whose phase is different from the current flowing on the PVCC1 side by 180 degrees barely flows during a period of 0 μs to 0.5 μs, as illustrated in FIG. 5. On the other hand, during a period of 0.5 μs to 1.0 μs, the current on the PVCC2 side increases from approximately 0.5 A to 1.0 A for a period of approximately 0.5 μs.

Accordingly, by using a dual output type step-down DC-DC converter, it is possible to disperse the load by half (that is, configuring so as to output voltage of 2.5 V from each channel that uses 5 V as input voltage), and to reduce a peak value of the PWM current by half. As a result, it is possible to reduce a capacity of the power supply capacitor by half.

In addition, according to the present embodiment, a dual output type DC-DC converter is used. However, it is also possible to use a triple output type DC-DC converter. In such a case, it is preferable to output voltages whose phases are different by 120 degrees using a commonly-known circuit configuration. In addition, it is also possible to change the design to a quadruple output type (90 degrees), or the like.

In addition, according to the present embodiment, the output of the DC-DC converter is set to a completely equal load between CHs. However, it is also possible to have different loads, and even when doing so, it is possible to suppress a capacity of the capacitor to some extent.

In addition, according to the present embodiment, two DC-DC converters are used. However, one DC-DC converter, or three or more DC-DC converters may be used.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first semiconductor memory element group including a plurality of semiconductor memory elements;
a second semiconductor memory element group including a plurality of semiconductor memory elements; and
a circuit including an input terminal and first and second output terminals,
wherein a first voltage output through the first output terminal is supplied to the first semiconductor memory element group,
wherein a second voltage output through the second output terminal is supplied to the second semiconductor memory element group, and
wherein the first and second voltages have different phases.

2. The device according to claim 1, wherein
the phases of the first and second voltages are different by 180 degrees.

3. The device according to claim 1, wherein
the number of semiconductor memory elements in the first and second semiconductor memory element groups is the same.

4. The device according to claim 3, further comprising:
a controller configured to control the semiconductor memory elements in the first and second semiconductor memory element groups.

5. The device according to claim 4, wherein
the controller includes the same number of control channels as the total number of semiconductor memory elements in the first and second semiconductor memory element groups.

6. The device according to claim 5, wherein
the control channels are each connected to a respective one of the semiconductor memory elements in the first and second semiconductor memory element groups.

7. The device according to claim 1, wherein
a maximum voltage of the first voltage and a maximum voltage of the second voltage are approximately the same, and
a maximum voltage of a voltage supplied through the input terminal is approximately twice the maximum voltages of the first and second voltages.

8. The device according to claim 1, wherein
each semiconductor memory element includes a multi-chip package having a plurality of semiconductor chips.

9. A semiconductor memory device comprising:
a first semiconductor memory element group including a plurality of semiconductor memory elements;
a second semiconductor memory element group including a plurality of semiconductor memory elements; and
a circuit including an input terminal and first and second output terminals,
wherein a first voltage output through the first output terminal is supplied to the first semiconductor memory element group and has a first maximum,
wherein a second voltage output through the second output terminal is supplied to the second semiconductor memory element group and has a second maximum, and
wherein the first and second maximums are approximately the same and approximately one-half a maximum of a voltage supplied through the input terminal.

10. The device according to claim 9, wherein
the number of semiconductor memory elements in the first and second semiconductor memory element groups is the same.

11. The device according to claim 10, further comprising:
a controller configured to control the semiconductor memory elements in the first and second semiconductor memory element groups.

12. The device according to claim 11, wherein
the controller includes the same number of control channels as the total number of semiconductor memory elements in the first and second semiconductor memory element groups.

13. The device according to claim 12, wherein
the control channels are each connected to a respective one of the semiconductor memory elements in the first and second semiconductor memory element groups.

14. The device according to claim 9, wherein
each semiconductor memory element includes a multi-chip package having a plurality of semiconductor chips.

15. A semiconductor memory device comprising:
a first group of multi-chip packages including a plurality of non-volatile semiconductor memories;
a second group of multi-chip packages including a plurality of non-volatile semiconductor memories;
a controller which controls reading and writing of information from and to each of the non-volatile semiconductor memories in the first and second groups of multi-chip packages;
a first DC-DC converter configured to supply DC voltages to the controller;
a second DC-DC converter configured to supply DC voltages to the multi-chip packages; and
a connector through which a control signal is received to control the DC voltages supplied by the first and second DC-DC converters,
wherein the second DC-DC converter is configured to supply a first voltage to the first group of multi-chip packages and a second voltage, having a phase that is different from a phase of the first voltage, to the second group of multi-chip packages.

16. The device according to claim 15, wherein
the phases of the first and second voltages are different by 180 degrees.

17. The device according to claim 16, wherein
the number of multi-chip packages in the first and second groups is the same.

18. The device according to claim 17, wherein
the controller includes the same number of control channels as the total number of multi-chip packages in the first and second groups.

19. The device according to claim 18, wherein
the control channels are each connected to a respective one of the multi-chip packages in the first and second groups.

20. The device according to claim 15, wherein
a maximum voltage of the first voltage and a maximum voltage of the second voltage are approximately the same, and
a maximum voltage of an input voltage supplied to the second DC-DC converter is approximately twice the maximum voltages of the first and second voltages.
